(19) United States
(12) Patent Application Publication
(10) Pub. No.: US 2024/0210843 A1
(43) Pub. Date: Jun. 27, 2024

(54) CONTROL APPARATUS, LITHOGRAPHY APPARATUS, AND ARTICLE MANUFACTURING METHOD

(71) Applicant: CANON KABUSHIKI KAISHA, Tokyo (JP)

(72) Inventor: NOZOMU HAYASHI, Tochigi (JP)

(21) Appl. No.: 18/542,946

(22) Filed: Dec. 18, 2023

(30) Foreign Application Priority Data
Dec. 22, 2022 (JP) 2022-205988
Aug. 22, 2023 (JP) 2023-135010

(51) Int. Cl. G03F 9/00; G03F 7/00

(52) U.S. Cl. CPC G03F 9/7042; G03F 7/0002; G03F 9/7046; G03F 9/7084; G03F 9/7088

(57) ABSTRACT

A control apparatus for controlling a position of a movable object is provided. The apparatus includes a measurer configured to measure the position of the movable object, a feedback controller configured to perform feedback control of the position of the movable object in a predetermined cycle so as to reduce a deviation of a measurement value obtained by the measurer with respect to a target value, and a controller configured to control the measurer. The measurer includes an image sensor including a plurality of pixels, and the controller adjusts a charge accumulation period of the pixels so that the measurement is repeatedly performed N times (N is an integer not less than 2) in the predetermined cycle, and the measurer provides a statistic value of obtained N measurement values to the feedback controller.

### BACKGROUND OF THE INVENTION

### Field of the Invention

The present invention relates to a control apparatus, a lithography apparatus, and an article manufacturing method.

### Description of the Related Art

In a lithography apparatus used in manufacturing semiconductor devices or the like, it is generally required to accurately position a stage that holds a substrate and/or a stage that holds an original.

One of lithography apparatuses is an imprint apparatus. An imprint apparatus forms a pattern of formable material (imprint material) on a substrate by curing the imprint material in a state in which an original and the imprint material are in contact with each other, and separating the original from the cured imprint material. In the imprint apparatus, it is necessary to correctly align the original and the substrate in the state in which the original and the imprint material are in contact with each other. As an alignment method in the imprint apparatus, for example, a dye-by-dye alignment method is adopted. The dye-by-dye alignment method is a method of performing alignment by detecting an alignment mark formed in a shot region of a substrate and an alignment mark formed on an original.

The accuracy of detecting an alignment mark is influenced by an illumination condition (a wavelength, a light amount, and the like) when illuminating the alignment mark. Japanese Patent Laid-Open No. 2021-57511 proposes a method of optimizing an illumination condition when detecting an alignment mark. According to Japanese Patent Laid-Open No. 2021-57511, after adjusting an illumination condition of a first shot region, an illumination condition of a second shot region is obtained by function approximation based on the adjusted illumination condition of the first shot region.

When imprinting a plurality of shot regions, if an illumination condition is changed for each shot region, it takes time to perform an operation of changing the illumination condition (for example, to change an ND filter), and thus throughput may deteriorate. As described in Japanese Patent Laid-Open No. 2021-57511, the illumination condition can be changed by changing an imaging period (charge accumulation period) by an image sensor of an alignment scope. However, if only the charge accumulation period is simply changed, a control cycle in feedback control of alignment unwantedly changes, and it may become difficult to correctly perform control (alignment) of the stage.

### SUMMARY OF THE INVENTION

The present invention provides a technique advantageous in both alignment accuracy of a movable object and throughput.

The present invention in its one aspect provides a control apparatus for controlling a position of a movable object, including a measurer configured to measure the position of the movable object, a feedback controller configured to perform feedback control of the position of the movable object in a predetermined cycle so as to reduce a deviation of a measurement value obtained by the measurer with respect to a target value, and a controller configured to control the measurer, wherein the measurer includes an image sensor including a plurality of pixels each of which converts incident light into an electrical signal and accumulates charges, and the controller adjusts a charge accumulation period of the plurality of pixels so that the measurement is repeatedly performed N times (N is an integer not less than 2) in the predetermined cycle, and the measurer provides a statistic value of obtained N measurement values to the feedback controller.

Further features of the present invention will become apparent from the following description of exemplary embodiments (with reference to the attached drawings).

### BRIEF DESCRIPTION OF THE DRAWINGS

FIG. 1 is a view showing the arrangement of an imprint apparatus;

FIG. 2 is a view showing examples of alignment marks;

FIGS. 3A and 3B are flowcharts of an imprint method;

FIG. 4 is a view showing an example of a plurality of alignment marks formed in a shot region;

FIG. 5 is a control block diagram of a feedback controller;

FIGS. 6A and 6B are views each showing the relationship between an accumulation period and a timing of obtaining a measurement value;

FIG. 7 is a view for explaining an article manufacturing method; and

FIGS. 8A and 8B are flowcharts of an imprint method.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

In the following embodiments, the present invention will be described by exemplifying an imprint apparatus that forms a pattern in an imprint material on a substrate using a mold as an original. However, the present invention is not limited to the imprint apparatus. For example, the present invention can be applied to another lithography apparatus such as an exposure apparatus that transfers a pattern of an original to a substrate via a projection optical system. In addition, the present invention can be applied to not only the lithography apparatus but also any apparatus that positions a control target object. In the following embodiments, a substrate stage that can move while holding a substrate will mainly be described as a control target. However, the present invention can be applied even in a case where an original stage that can move while holding an original or the like is a control target.

Firstly, an overview of an imprint apparatus according to an embodiment will be described. The imprint apparatus is an apparatus that brings an imprint material supplied onto a substrate into contact with a mold and supplies curing energy to the imprint material to form a pattern of the cured material to which a concave-convex pattern of the mold is transferred.

As an imprint material, a curable composition (to be sometimes called an uncured resin) that is cured upon application of curing energy is used. As curing energy, electromagnetic waves, heat, or the like can be used. Electromagnetic waves can be, for example, light selected from the wavelength range of 10 nm or more and 1 mm or less, for example, infrared light, visible light, or ultraviolet light, or the like. A curable composition can be a composition that is cured by being irradiated with light or by being heated. Of these compositions, a photo-curable composition that is cured by being irradiated with light contains at least a polymerizable compound and a photopolymerization initiator, and may further contain a non-polymerizable compound or a solvent, as needed. A non-polymerizable compound is at least one type of compound selected from the group consisting of a sensitizer, hydrogen donor, internal mold release agent, surfactant, antioxidant, and polymer component. An imprint material supply apparatus can arrange an imprint material on a substrate in the form of droplets or islands or films formed from a plurality of droplets connected to each other. The viscosity (the viscosity at 25° C.) of the imprint material can be, for example, 1 mPa·s or more and 100 mPa·s or less. As a material for a substrate, for example, glass, ceramic, metal, semiconductor, or resin can be used. The surface of a substrate may be provided with a member made of a material different from that of the substrate, as needed. For example, a silicon wafer, a compound semiconductor wafer, silica glass, or the like is used as the substrate.

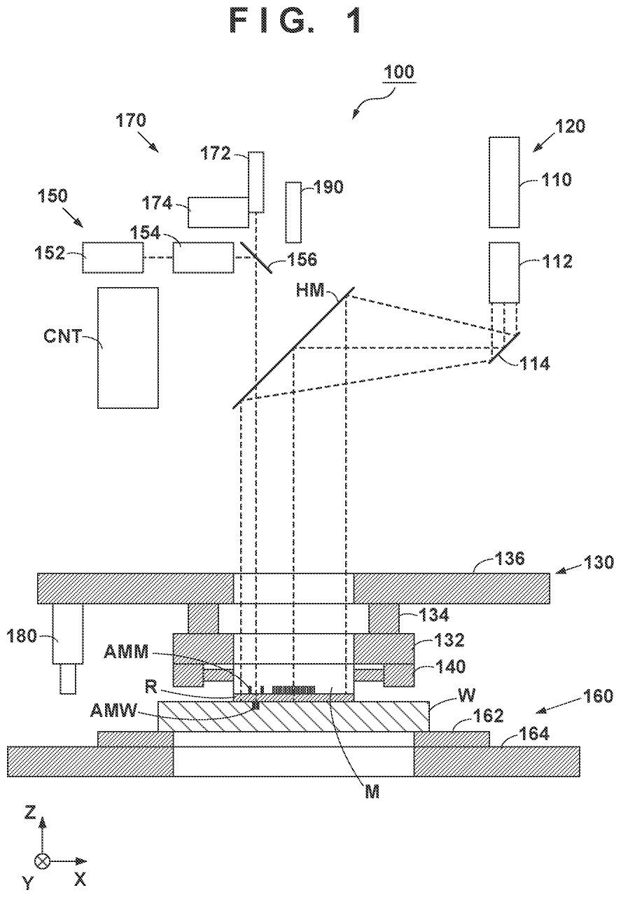

FIG. 1 is a view showing the arrangement of an imprint apparatus 100 according to an embodiment. In this specification and the accompanying drawings, directions are indicated on an XYZ coordinate system having a horizontal plane as the X-Y plane. In general, a substrate W that is a substrate to be exposed is placed on a substrate stage 164 so that the surface of the substrate is parallel to the horizontal plane (X-Y plane). In the following description, directions orthogonal to each other within the plane along the surface of the substrate W are set as the X-axis and the Y-axis, respectively, and a direction perpendicular to the X-axis and the Y-axis is set as the Z-axis.

Assume that the imprint apparatus 100 adopts a photo-curing method of curing an imprint material by irradiating it with ultraviolet light. Therefore, in this embodiment, an imprint material R is a photo-curable material. However, the method of curing the imprint material is not limited to this, and a heat-curing method of curing an imprint material by applying heat can also be adopted.

The imprint apparatus 100 is configured to form a pattern in a plurality of shot regions of the substrate W by repeating an imprint cycle. In one imprint cycle, the imprint apparatus 100 forms a pattern in one shot region of the substrate W by curing the imprint material R in a state in which an original M (mold) is in contact with the imprint material R on the substrate W. The imprint apparatus 100 can include, for example, a curing unit 120, an imprint head 130, an original corrector 140, an alignment illumination apparatus 150, a substrate driver 160, an alignment mechanism 170, and a controller CNT.

The curing unit 120 cures the imprint material R by irradiating the imprint material R with ultraviolet light via the original M. The curing unit 120 can include a light source unit 110 and an optical system 112. The light source unit 110 can include, for example, a light source such as a halogen lamp that generates ultraviolet light (for example, an i-line or a g-line), and an ellipse mirror that condenses light generated by the light source. The optical system 112 can include a lens, a half mirror HM, and a mirror 114 that are used to irradiate the imprint material R in the shot region with light from the light source unit 110. The optical system 112 may include an optical integrator for uniformly illuminating the original M. Light whose range is defined by an aperture enters the imprint material R on the substrate W via an imaging system and the original M. A scope 190 is a scope for observing the entire shot region. The scope 190 is used to check the state of the imprint material and the progress of filling of the imprint material.

The original M is formed by a transparent material at the wavelength of ultraviolet light, for example, quartz, to transmit ultraviolet light for curing the imprint material R. The original M can be conveyed by an original conveyance mechanism (not shown). The original conveyance mechanism can include, for example, a conveyance robot including a chuck such as a vacuum chuck.

The imprint head 130 is an original stage that moves while holding the original M. The imprint head 130 can include, for example, an original chuck 132 that holds the original M, an original driver 134 that drives the original M by driving the original chuck 132, and an original base 136 that supports the original driver 134. The original driver 134 can include a positioning mechanism that controls the position of the original M with respect to six axes. The six axes are the X-axis, the Y-axis, the Z-axis, and rotations about these axes. The original driver 134 can further include a mechanism that brings the original M into contact with the imprint material R on the substrate W and separates the original M from the cured imprint material R. The original corrector 140 can be mounted on the original chuck 132. The original corrector 140 can correct the shape of the original M by pressurizing the original M from the peripheral direction using cylinders acting by a fluid such as air or oil. Alternatively, the original corrector 140 can include a temperature controller that controls the temperature of the original M and correct the shape of the original M by controlling the temperature of the original M. The substrate W can deform (typically expand or contract) via a process such as a heat treatment. The original corrector 140 can correct the shape of the original M in accordance with the deformation of the substrate W such that an overlay error falls within an allowable range.

A supplier 180 sequentially supplies the imprint material R to the imprint regions (shot regions) of the substrate W under the control of the controller CNT. The supplier 180 can include, for example, a tank that stores the imprint material, a nozzle that discharges the imprint material supplied from the tank via a supply path onto the substrate W, a valve provided in the supply path, and a supply amount controller that controls the supply amount of the imprint material. Alternatively, the supplier 180 may be configured to supply the imprint material R to the entire surface of the substrate W at once. Instead of the supplier 180 arranged in the imprint apparatus 100, an external supply apparatus may supply the imprint material R to the entire surface of the substrate W at once.

After the supplier 180 supplies the imprint material R onto the substrate, the imprint head 130 is controlled to bring the original M into contact with the imprint material R. In this state, the curing unit 120 irradiates the imprint material R with ultraviolet light, thereby curing the imprint material R. After that, the imprint head 130 is controlled to separate the original M from the cured imprint material R.

The substrate driver 160 can include, for example, a substrate chuck 162 that holds the substrate W, the substrate stage 164 that drives the substrate W by driving the substrate chuck 162, and a stage driving mechanism (not shown). The stage driving mechanism can include a positioning mechanism that controls the position of the substrate W by controlling the position of the substrate stage 164 with respect to the above-described six axes.

The alignment mechanism 170 and the controller CNT that controls the alignment mechanism 170 form a measurer that measures a positional shift between the original M and the substrate W. The alignment mechanism 170 can include, for example, an alignment scope 172 and an alignment stage mechanism 174. The alignment scope 172 can include an Automatic Adjustment Scope (AAS) that aligns the original M and the shot region of the substrate W. The alignment scope 172 detects, via the original M, an alignment mark formed on the original M and an alignment mark formed on the substrate W. FIG. 1 shows only one alignment mechanism 170 but a plurality of alignment mechanisms 170 may be provided.

The controller CNT can be formed by, for example, a computer (information processing apparatus) including a CPU and a memory. The controller CNT controls the operation of the imprint apparatus 100 based on a computer program stored in the memory. For example, the controller CNT controls the position of the substrate stage 164 as a movable object. The memory (not shown) of the controller CNT can store data associated with control of the substrate stage 164.

The alignment scope 172 includes an image sensor including a plurality of pixels each of which converts incident light into an electrical signal and accumulates charges. In this embodiment, the alignment scope 172 can include an image sensor including a plurality of pixels each of which converts light from each of an original-side alignment mark formed on the original M and a substrate-side alignment mark formed on the substrate W into an electrical signal and accumulates charges. The alignment scope 172 performs imaging during a set charge accumulation period (to be simply referred to as an “accumulation period” hereinafter).

As described above, the alignment scope 172 and the controller CNT (or a dedicated image processor (not shown)) can form a measurer that measures a positional shift between the original M and the substrate W. The controller CNT calculates a relative position between the original-side alignment mark and the substrate-side alignment mark in an alignment mark image obtained by imaging of the alignment scope 172. The controller CNT obtains a measurement value representing a shape difference between the original M and the shot region of the substrate W based on the calculated relative position. The measurement value can include coordinates, a rotation, a magnification, and a trapezoid component.

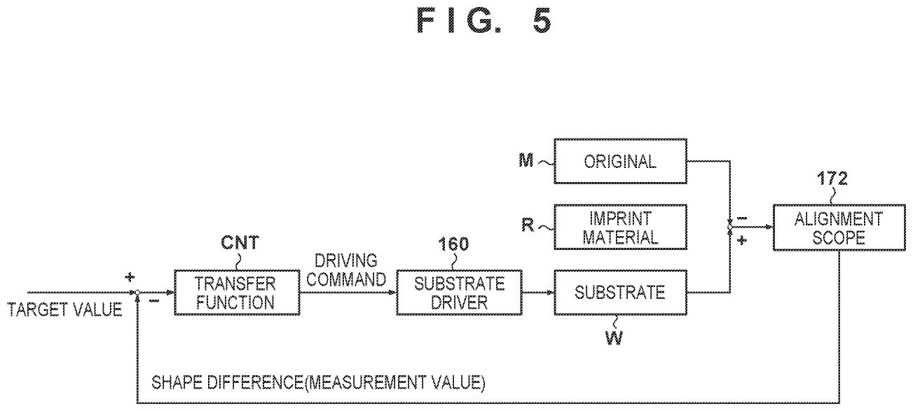

The imprint apparatus 100 forms a feedback controller that performs feedback control of the position of at least one of the original M and the substrate W in a predetermined cycle so as to reduce a deviation of the obtained measurement value with respect to a target value. FIG. 5 shows a control block diagram of the feedback controller. As shown in FIG. 5, the difference between the measured shape difference (measurement value) and the target value is input, and a driving amount as a driving command for the substrate driver 160 is calculated by a transfer function set in the controller CNT. Control parameters used in the transfer function include parameters of a proportional gain, an integral gain, a differential gain, the frequency of a notch filter, the cutoff frequency of a low-pass filter, and the like. These parameters are optimized in accordance with the repetition frequency of the accumulation period set in the alignment scope 172.

The alignment illumination apparatus 150 can include a light source 152 such as a laser diode, a light amount adjuster 154, and a half mirror 156 that composites light exiting from the light amount adjuster 154 and light on the optical axis of the alignment mechanism 170. The light amount adjuster 154 adjusts an amount of light entering the image sensor. The light amount adjuster 154 can include, for example, an ND filter.

The imprint apparatus 100 can further include a base and a vibration isolator (not shown). The base forms a reference plane when the substrate stage 164 moves while supporting the whole imprint apparatus 100. The vibration isolator removes a vibration from the floor, and supports the base.

### First Embodiment

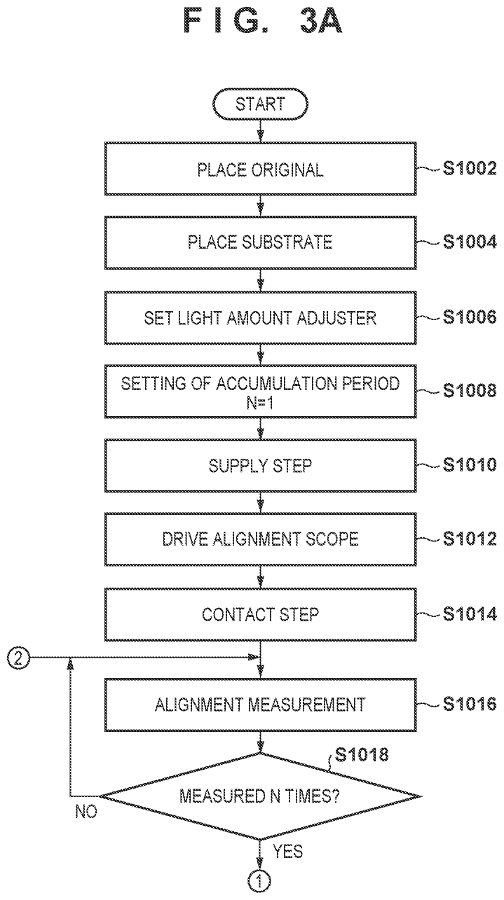

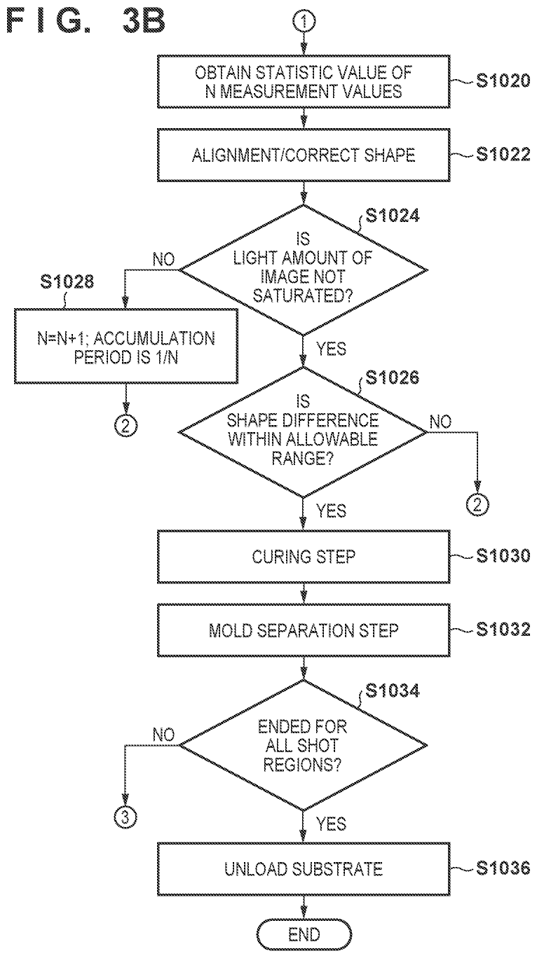

An imprint method executed by an imprint apparatus 100 will be described with reference to FIGS. 3A-B. In step S1002, a controller CNT controls an original conveyance apparatus (not shown) to convey an original M onto an original chuck 132. The original M is held by the original chuck 132. In step S1004, the controller CNT controls a substrate conveyance apparatus (not shown) to convey a substrate W onto a substrate chuck 162. The substrate W is held by the substrate chuck 162. In this example, on the substrate W, a pattern of at least one layer has already been formed together with an alignment mark.

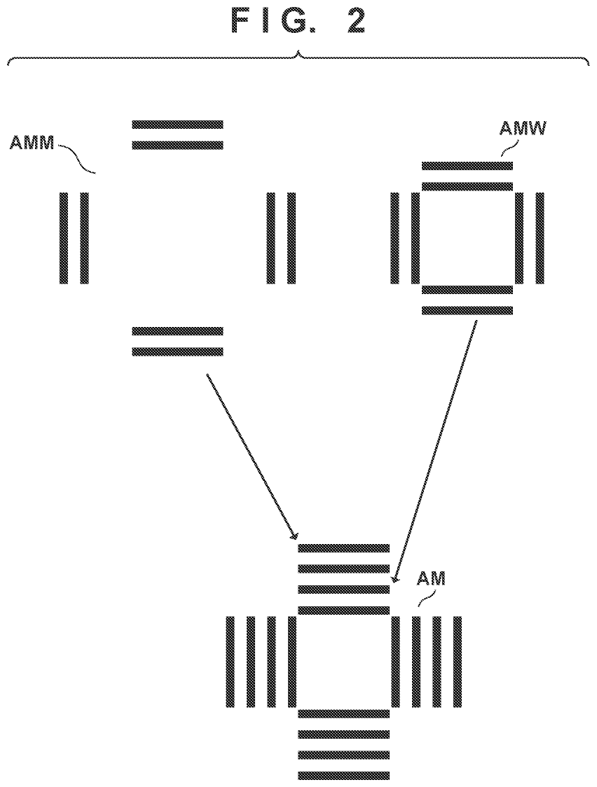

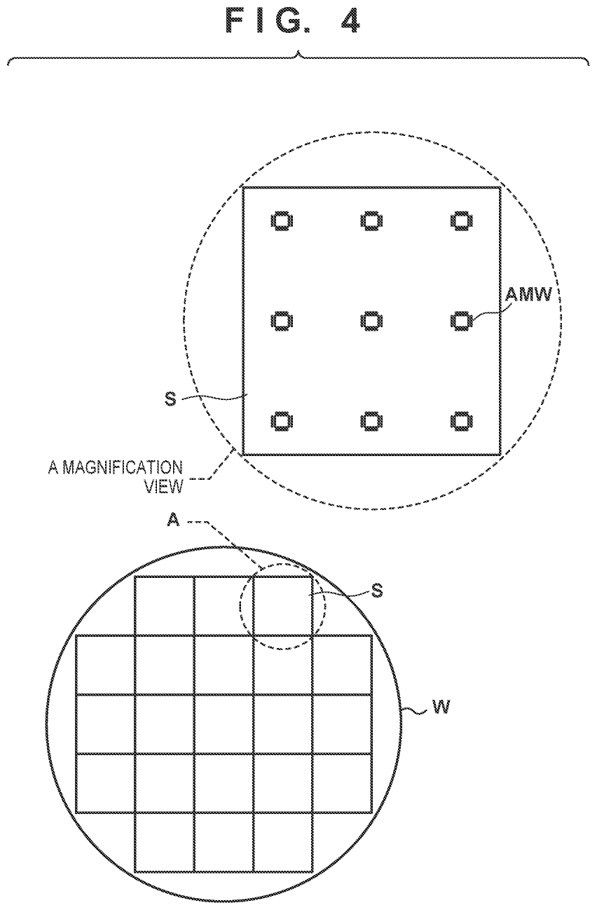

FIG. 2 exemplifies alignment marks formed on the original M and the substrate W. In a planar view viewed from an alignment scope 172, an original-side alignment mark AMM formed on the original M and a substrate-side alignment mark AMW formed on the substrate W do not overlap each other. In this embodiment, the controller CNT acquires, from the alignment scope 172, an alignment mark image AM including the original-side alignment mark AMM and the alignment mark AMW on the substrate W. The controller CNT can measure the relative position between the marks based on the alignment mark image AM. As shown in FIG. 4, a plurality of shot regions S are formed on the substrate W. In each of the plurality of shot regions S, a plurality of alignment marks AMW can be formed.

In step S1006, the controller CNT sets a light amount adjuster 154. Assume that a proper imaging condition under which the high-quality alignment mark image AM is obtained by the alignment scope 172 is examined in advance by the method described in Japanese Patent Laid-Open No. 2021-57511. The controller CNT adjusts the light amount adjuster 154 with reference to a darkest shot region, among the plurality of shot regions of the substrate W, specified based on a measurement result of light amount unevenness in the surface of the substrate W, which has been obtained in advance.

In this embodiment, the controller CNT adjusts the accumulation period of the plurality of pixels of the alignment scope 172 so that measurement is repeatedly performed N times (N is an integer of 2 or more) in a control cycle (predetermined cycle) of a feedback controller. Then, the controller CNT provides the statistic value of obtained N measurement values to the feedback controller. More specifically, in step S1008, the controller CNT sets the accumulation period of the alignment scope 172. At this time, the initial value of the parameter N representing a measurement repetition count is set to 1.

In step S1010, the controller CNT controls a substrate driver 160 and a supplier 180 to supply an imprint material R onto the shot region (supply step). Note that as described above, instead of supplying the imprint material R onto the shot region using the supplier 180, the imprint material may be supplied to the entire surface of the substrate W at once using an external imprint material supply apparatus.

In step S1012, the controller CNT controls an alignment stage mechanism 174 to locate the alignment scope 172 at the position of the original-side alignment mark.

In step S1014, the controller CNT controls an original driver 134 to lower the original M so that the original M and the imprint material R on the substrate W come into contact with each other (contact step). At this time, the controller CNT may control the substrate driver 160 to raise the substrate W so that the original M and the imprint material R on the substrate W come into contact with each other. Alternatively, the controller CNT may control the original driver 134 to lower the original M and control the substrate driver 160 to raise the substrate W so that the original M and the imprint material R on the substrate W come into contact with each other. A load applied by this contact on the imprint material R can be controlled using, for example, a load sensor incorporated in the original driver 134.

In a processing loop of steps S1016 to S1028, alignment measurement is performed in accordance with a dye-by-dye alignment method. More specifically, in step S1016, the controller CNT acquires the alignment mark image AM captured by the alignment scope 172, and measures the alignment mark relative position between the original M and the substrate W. Based on the measurement result of the alignment mark relative position, the controller CNT obtains, as a measurement value, a shape difference (coordinates, a rotation, a magnification, a trapezoid component, and the like) representing a difference in shot shape between the original M and the substrate W.

In step S1018, the controller CNT determines whether the measurement count has reached N (the initial value of N has been set to 1 in step S1008). If the measurement count has not reached N, the process returns to step S1016 and alignment measurement is repeated. In step S1020, the controller CNT obtains the statistic value of the obtained N measurement values. The statistic value can be one of an average value, a weighted average value, a mode, and a median. Assume here that the statistic value is an average value. In step S1022, the alignment scope 172 as the measurer provides, to the feedback controller, the average value as the statistic value of the obtained N measurement values. This causes the feedback controller to align the original M and the shot region of the substrate W. At this time, an original corrector 140 corrects the shape of the original M to match with the shape of the shot region of the substrate W.

The controller CNT decides the value of N so as to suppress saturation of the amount of light entering the plurality of pixels in the alignment scope 172. For example, in step S1024, the controller CNT determines whether the light amount of the image of the alignment scope 172 is saturated. This determination processing can be performed based on, for example, whether the ratio of a region, where luminance is saturated (so-called highlight detail loss occurs), with respect to the alignment mark image AM exceeds a predetermined value. If the light amount of the image is saturated, the process advances to step S1028. In step S1028, the controller CNT increments the value of N by one, and changes the accumulation period to 1/N, and then the process returns to step S1016.

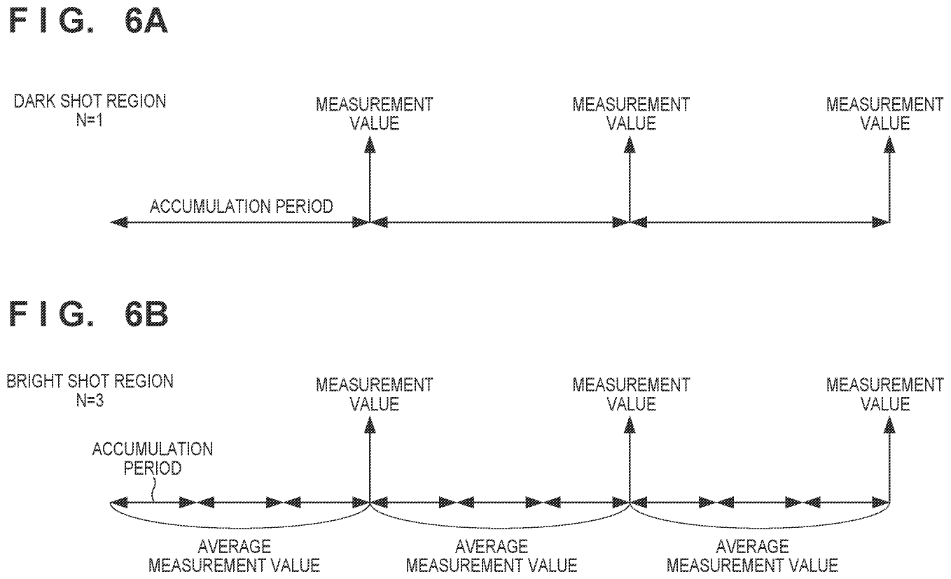

The relationship between the accumulation period and the timing of obtaining the measurement value will be described with reference to FIGS. 6A and 6B. FIG. 6A shows the relationship between the accumulation period and the timing of obtaining the measurement value for N=1. In this case, the measurement value is obtained from the alignment image obtained by imaging during a predetermined accumulation period. FIG. 6B shows the relationship between the accumulation period and the timing of obtaining the measurement value for N=3. In this case, the predetermined accumulation period is set to 1/N (in this example, 1/3), and measurement is repeated N times (in this example, three times), thereby obtaining the average of the measurement values obtained by the measurement operations. The operation shown in FIG. 6B is the same as an operation of repeatedly performing measurement at the same frequency as in FIG. 6A. Therefore, in the control block diagram shown in FIG. 5, alignment is correctly performed without changing control parameters used in a transfer function set in the controller CNT. The accumulation period can be changed instantaneously since mechanical driving performed by the light amount adjuster 154 is not performed. Therefore, this does not degrade throughput.

In the correction of the shape of the original M performed in step S1022, a correction error caused by a driving error of the original corrector 140 or the like may occur. To cope with this, in step S1026, the controller CNT determines whether the shape difference between the original M and the shot region of the substrate W falls within allowable range. If the shape difference falls outside the allowable range, the process returns to step S1016. In this way, the shape of the original M is corrected until the shape difference falls within the allowable range. If the shape difference falls within the allowable range, the process advances to step S1030.

In step S1030, the controller CNT controls the curing unit 120 to start curing the imprint material R (curing step). After the completion of curing, in step S1032, the controller CNT controls the original driver 134 to separate the original M from the cured imprint material on the substrate W (mold separation step). Mold separation may be performed by causing the substrate driver 160 to drive the substrate W, instead of the original driver 134. Alternatively, mold separation may be performed by causing both the original driver 134 and the substrate driver 160 to drive the original M and the substrate W, respectively.

In step S1034, the controller CNT determines whether imprint has ended for all the shot regions of the substrate W. If there is a shot region for which imprint has not been performed, the process returns to step S1008, and the processing is repeated for the next shot region. If imprint has ended for all the shot regions, the process advances to step S1036. In step S1036, the controller CNT cancels holding of the substrate W by the substrate chuck 162, and controls the substrate conveyance apparatus to unload the substrate W to the outside of the imprint apparatus 100.

In the above-described embodiment, the initial value of the parameter N representing the measurement repetition count is set to 1 in step S1008. However, the present invention is not limited to this. For example, a change in light amount in the substrate W can be predicted in advance by the method described in Japanese Patent Laid-Open No. 2021-57511. In a case where the target shot region is predicted as a bright shot region, a value of 2 or more may be set as the initial value of N. In a case where a plurality of alignment mechanisms 170 are mounted, the accumulation period may be changed for all the alignment scopes at the same time.

In the above-described example, alignment measurement is performed N times in steps S1016 to S1020, thereby obtaining the average of the N measurement values. However, processing of generating an average image of N alignment mark images obtained by the measurement operations and obtaining a measurement value from the generated average image may be performed.

In the above-described example, if it is determined in step S1026 that the shape difference falls within the allowable range, the process advances to step S1030 (curing step). However, if a preset time elapses since the start of alignment, the process may forcibly advance to the next step regardless of the value of the shape difference.

According to the above-described embodiment, since it is unnecessary to change a light amount adjuster such as an ND filter for each shot region, throughput does not deteriorate. Furthermore, according to the above-described embodiment, in accordance with the brightness of the alignment scope, the measurement repetition count is changed while the accumulation period is changed. At this time, the control cycle (the above-described predetermined cycle) in feedback control of alignment remains unchanged. Therefore, it is possible to correctly perform control (alignment) of a movable object without changing the control parameters, and necessary alignment accuracy of the movable object is ensured.

### Second Embodiment

In the above-described first embodiment, as shown in FIGS. 3A-B, the initial value of the parameter N representing the measurement repetition count is set to 1 in step S1008 for all the shot regions, but the initial value may be set to a value other than 1. For example, in a case where alignment is completed without saturating a light amount in the immediately preceding shot region for N=3, the initial value of a parameter N may be set to 3 for the next shot region and a processing loop from step S1008 may be started. The parameter N obtained in the identical shot region of the immediately preceding substrate, instead of the immediately preceding shot region, may be taken over.

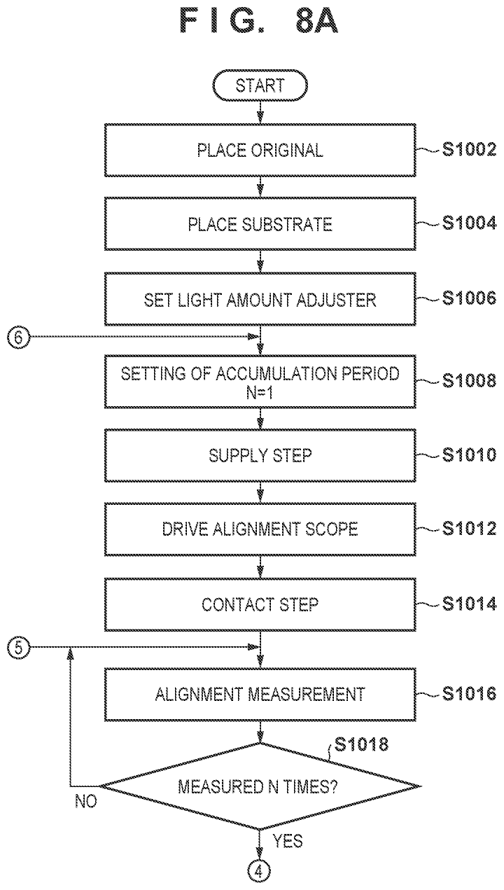

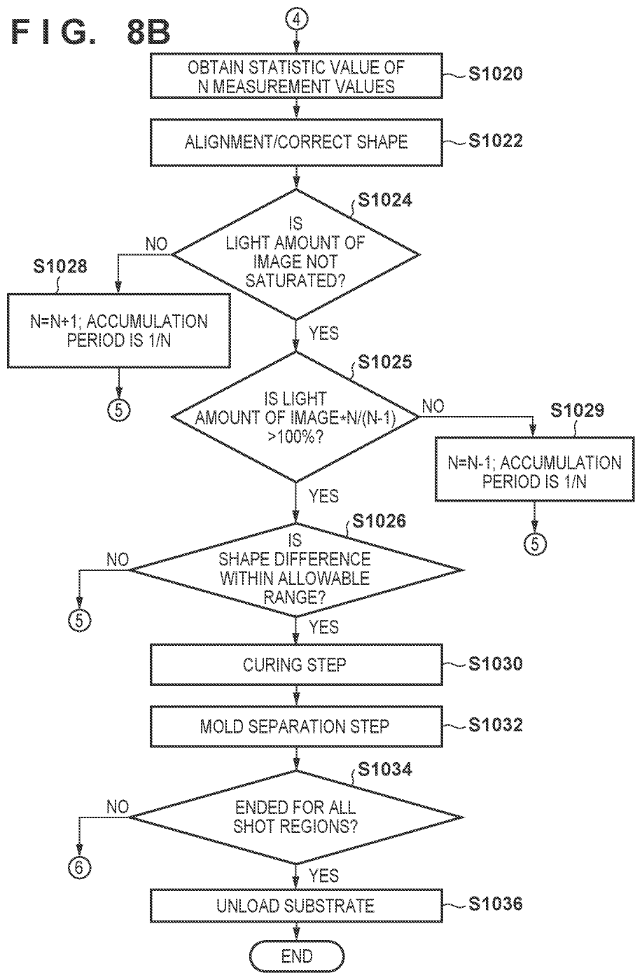

An imprint method according to the second embodiment will be described with reference to a flowchart shown in FIGS. 8A-B. When comparing FIGS. 8A-B with FIGS. 3A-B, steps S1025 and S1029 are added in FIG. 8B. In FIGS. 3A-B, the initial value of the parameter N representing the measurement repetition count is fixed to 1. On the other hand, in FIGS. 8A-B, the initial value is set to a variable N0. In the second embodiment, before imprinting each shot region, a controller CNT sets the initial value of the parameter N representing the measurement repetition count is set to N0 in step S1008. N0 can be set to the value of N obtained in the immediately preceding shot region or the value of N obtained in the identical shot region of the immediately preceding substrate.

Steps other than steps S1008, S1025, and S1029 in FIGS. 8A-B are the same as in FIGS. 3A-B. For example, in the second embodiment, alignment between an original M and a shot region of a substrate W (step S1022) and determination of saturation of a light amount (step S1024) are performed in the same manner as in the first embodiment. A description of the same steps as in FIGS. 3A-B will be omitted. Steps S1025 and S1029 that are added will be described below.

In the second embodiment, a case where an image is too dark when the initial value of the measurement repetition count N is not 1 is considered. If an image is dark, the reliability of measurement processing may deteriorate. To cope with this, in the second embodiment, the controller CNT determines in step S1025 whether the light amount is saturated when the measurement repetition count N is decreased. For example, the controller CNT determines whether a value obtained by multiplying the light amount of the image by N/(N−1) exceeds 100% representing a saturated light amount. If the value obtained by multiplying the light amount of the image by N/(N−1) does not exceed 100% representing the saturated light amount, the light amount of the image is much lower than a saturation level, and it is determined that the image is dark. In this case, the process advances to step S1029. In step S1029, the controller CNT decrements the value of N by one (N=N−1), and changes the accumulation period to 1/N, and then the process returns to step S1016. In this way, it is possible to shorten the time taken to adjust the measurement repetition count N.

### <Embodiment of Method of Manufacturing Article>

The pattern of a cured product formed using an imprint apparatus is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, a SRAM, a flash memory, and a MRAM and semiconductor elements such as an LSI, a CCD, an image sensor, and an FPGA. Examples of the mold are molds for imprint.

The pattern of the cured product is directly used as at least some of the constituent members of the above-described articles or used temporarily as a resist mask. After etching or ion implantation is performed in the substrate processing step, the resist mask is removed.

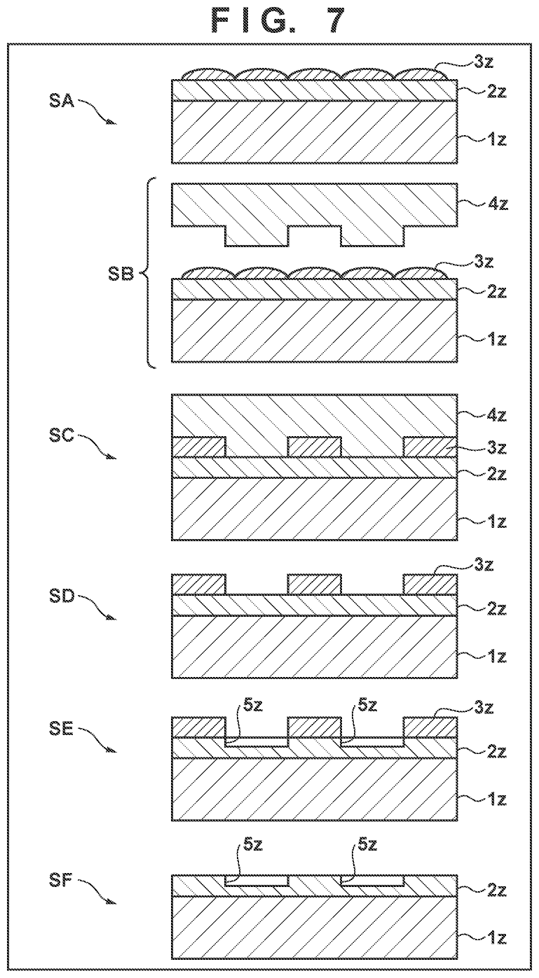

A method of manufacturing an article will be described next. As shown step SA of FIG. 7, a substrate 1z such as a silicon wafer with a processed material 2z such as an insulator formed on the surface is prepared. Next, an imprint material 3z is applied to the surface of the processed material 2z by an inkjet method or the like. A state in which the imprint material 3z is applied as a plurality of droplets onto the substrate is shown here.

As shown in step SB of FIG. 7, a side of a mold 4z for imprint with an uneven pattern is directed toward and made to face the imprint material 3z on the substrate. As shown in step SC of FIG. 7, the substrate 1z to which the imprint material 3z is applied is brought into contact with the mold 4z, and a pressure is applied. The gap between the mold 4z and the processed material 2z is filled with the imprint material 3z. In this state, when the imprint material 3z is irradiated with energy for curing via the mold 4z, the imprint material 3z is cured.

As shown in step SD of FIG. 7, after the imprint material 3z is cured, the mold 4z is separated from the substrate 1z. Then, the pattern of the cured product of the imprint material 3z is formed on the substrate 1z. In the pattern of the cured product, the concave portion of the mold corresponds to the convex portion of the cured product, and the convex portion of the mold corresponds to the concave portion of the cured product. That is, the uneven pattern of the mold 4z is transferred to the imprint material 3z.

As shown in step SE of FIG. 7, when etching is performed using the pattern of the cured product as an etching resistant mask, a portion of the surface of the processed material 2z where the cured product does not exist or remains thin is removed to form a groove 5z. As shown in step SF of FIG. 7, when the pattern of the cured product is removed, an article with the grooves 5z formed in the surface of the processed material 2z can be obtained. Here, the pattern of the cured product is removed. However, instead of processing or removing the pattern of the cured product, it may be used as, for example, an interlayer dielectric film included in a semiconductor element or the like, that is, a constituent member of an article.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-205988, filed Dec. 22, 2022, and Japanese Patent Application No. 2023-135010, filed Aug. 22, 2023, which are hereby incorporated by reference herein in their entirety.

What is claimed is:

1. A control apparatus for controlling a position of a movable object, comprising:
a measurer configured to measure the position of the movable object;
a feedback controller configured to perform feedback control of the position of the movable object in a predetermined cycle so as to reduce a deviation of a measurement value obtained by the measurer with respect to a target value; and
a controller configured to control the measurer,
wherein the measurer includes an image sensor including a plurality of pixels each of which converts incident light into an electrical signal and accumulates charges, and
the controller adjusts a charge accumulation period of the plurality of pixels so that the measurement is repeatedly performed N times (N is an integer not less than 2) in the predetermined cycle, and the measurer provides a statistic value of obtained N measurement values to the feedback controller.

2. The apparatus according to claim 1, wherein the controller decides a value of N so as to suppress saturation of an amount of light entering the plurality of pixels.

3. The apparatus according to claim 1, wherein the statistic value is one of an average value, a weighted average value, a mode, and a median.

4. A lithography apparatus for transferring a pattern of an original to a substrate, comprising:
a measurer configured to measure a positional shift between the original and the substrate;
a feedback controller configured to perform feedback control of a position of at least one of the original and the substrate in a predetermined cycle so as to reduce a deviation of a measurement value obtained by the measurer with respect to a target value; and
a controller configured to control the measurer,
wherein the measurer includes an image sensor including a plurality of pixels each of which converts light from each of an original-side alignment mark formed on the original and a substrate-side alignment mark formed on the substrate into an electrical signal and accumulates charges, and
the controller adjusts a charge accumulation period of the plurality of pixels so that the measurement is repeatedly performed N times (N is an integer not less than 2) in the predetermined cycle, and the measurer provides a statistic value of obtained N measurement values to the feedback controller.

5. The apparatus according to claim 4, wherein based on a relative position between the original-side alignment mark and the substrate-side alignment mark in an alignment mark image obtained from the image sensor, the measurer obtains a measurement value representing a shape difference between the original and a shot region of the substrate.

6. The apparatus according to claim 4, wherein the controller decides a value of N so as to suppress saturation of an amount of light entering the plurality of pixels.

7. The apparatus according to claim 6, wherein the controller decides the value of N for each of a plurality of shot regions of the substrate.

8. The apparatus according to claim 6, wherein
a plurality of measurers are provided, and
the same value of N is applied to each of the measurers.

9. The apparatus according to claim 4, further comprising a light amount adjuster configured to adjust an amount of light entering the image sensor,
wherein the light amount adjuster is adjusted with reference to a darkest shot region, among a plurality of shot regions of the substrate, specified based on a measurement result of light amount unevenness in a surface of the substrate, which has been obtained in advance.

10. The apparatus according to claim 4, wherein the lithography apparatus is an imprint apparatus configured to form a pattern in an imprint material on the substrate using a mold as the original.

11. The apparatus according to claim 4, wherein the lithography apparatus is an exposure apparatus configured to transfer a pattern of the original to the substrate via a projection optical system.

12. An article manufacturing method comprising:
forming a pattern on a substrate using a lithography apparatus defined in claim 4; and
processing the substrate with the pattern formed thereon,
wherein an article is manufactured from the processed substrate.
